(19) United States
(12) Patent Application Publication
(10) Pub. No.: US 2008/0252634 A1
(43) Pub. Date: Oct. 16, 2008

(54) Integrated circuit device and electronic instrument

(75) Inventors: Shinya Sato, Suwa-shi (JP); Takayuki Saiki, Suwa-shi (JP); Hiroyuki Takamiya, Chino-shi (JP); Masaaki Abe, Chino-shi (JP)

Correspondence Address: OLIFF & BERRIDGE, PLC, P.O. BOX 320850, ALEXANDRIA, VA, 22320-4850, US

(73) Assignee: SEIKO EPSON CORPORATION, TOKYO (JP)

(21) Appl. No.: 12/081,008

(22) Filed: Apr. 9, 2008

(30) Foreign Application Priority Data
Apr. 12, 2007 (JP) 2007-105040

(51) Int. Cl. G06F 3/038; H03K 19/0175

(52) U.S. Cl. 345/211; 326/80

(57) ABSTRACT

An integrated circuit device includes a first circuit block that includes low-voltage transistors (LVTr) and operates using a first high-potential power supply voltage and a first low-potential power supply voltage, a second circuit block that includes low-voltage transistors (LVTr) and operates using a second high-potential power supply voltage and a second low-potential power supply voltage that differ in power supply system from the first circuit block, and an interface circuit (I/O buffer) provided between the first circuit block and the second circuit block. The interface circuit (I/O buffer) includes medium-voltage transistors (MVTr: transistors of which the thickness of the gate insulating film is larger than that of the low-voltage transistors (LVTr)). An electrostatic discharge protection circuit formed of bidirectional diodes is provided between a first and second low-potential power supply nodes.

Japanese Patent Application No. 2007-105040 filed on Apr. 12, 2007, is hereby incorporated by reference in its entirety.

### BACKGROUND OF THE INVENTION

The present invention relates to an integrated circuit device with improved electrostatic discharge protection (electrostatic discharge resistance), an electronic instrument, and the like.

Along with an increase in the degree of integration and scaling down of integrated circuit devices (ICs), measures to prevent electrostatic discharge destruction (breakdown) have increasingly become important. Therefore, the IC manufacturer is required to produce highly reliable products which can pass a severe electrostatic discharge destruction test (e.g., JP-A-2000-206177).

JP-A-5-136328 discloses an electrostatic discharge protection circuit, for example.

An interface circuit provided between a first circuit block formed using a low-voltage transistor that operates utilizing a 1.8 V power supply and a second circuit block formed using a low-voltage transistor that operates utilizing a 1.8 V power supply in another system is normally formed using a low-voltage transistor that operates utilizing a 1.8 V power supply, for example.

The inventors of the invention discovered the following. Specifically, when an interface circuit formed using a low-voltage transistor that operates utilizing a 1.8 V power supply is provided between a first circuit block formed using a low-voltage transistor that operates utilizing a 1.8 V power supply and a second circuit block formed using a low-voltage transistor that operates utilizing a 1.8 V power supply in another system, and static electricity of different polarities is applied between the power supplies of the first circuit block and the second circuit block, a gate insulating film of an insulated gate transistor which forms the interface circuit may break through a special electrostatic discharge destruction mechanism.

In one example of the new electrostatic discharge destruction mechanism discovered by the inventors of the invention, the first circuit block operates using a first high-potential power supply and a first low-potential power supply, the second circuit block operates using a second high-potential power supply and a second low-potential power supply, and the first circuit block and the second circuit block transmit signals through a buffer circuit which includes a pair of input/output buffers which operate using different power supply systems (i.e., first and second power systems). In this case, at least one of a first buffer circuit which contributes to signal transmission from the first circuit block to the second circuit block and a second buffer circuit which contributes to signal transmission from the second circuit block to the first circuit block is provided. For example, a positive electrostatic surge is applied to the first high-potential power supply, and a negative electrostatic surge is applied to the second low-potential power supply. Note that a positive electrostatic surge may be applied to the second high-potential power supply, and a negative electrostatic surge may be applied to the first low-potential power supply.

According to one example of the new electrostatic discharge destruction mechanism, the electrostatic surge energy partially flows through the buffer circuit which includes the pair of input/output buffers (i.e., flows through a normal signal transmission route), whereby the gate insulating film of the transistor which forms the input buffer tends to break. This electrostatic discharge destruction mechanism also relates to an electrostatic discharge protection circuit inserted between the low-potential power supplies, power supply protection circuits respectively provided for different power supply systems, and the like.

### SUMMARY

According to one aspect of the invention, there is provided an integrated circuit device comprising:

a first circuit block;

a second circuit block that operates using a power supply system differing from that of the first circuit block; and

an interface circuit provided between the first circuit block and the second circuit block,

gate insulating films of some or all of a plurality of insulated gate transistors that form the interface circuit having a thickness larger than a thickness of a gate insulating film of at least one insulated gate transistor included in at least one of the first circuit block and the second circuit block.

According to another aspect of the invention, there is provided an electronic instrument comprising:

the above integrated circuit device; and

a display device driven by the integrated circuit device.

### BRIEF DESCRIPTION OF THE SEVERAL VIEWS OF THE DRAWING

FIG. 1 is a view showing an example of the basic configuration of an integrated circuit device according to the invention.

FIG. 2 is a circuit diagram showing a configuration example of an interface circuit (provided between circuits that differ in power supply system) according to a first example.

FIG. 3 is a circuit diagram showing a configuration example of an interface circuit (provided between circuits that differ in power supply system) according to a second example.

FIG. 4 is a circuit diagram showing a configuration example of an interface circuit (provided between circuits that differ in power supply system) according to a third example.

FIG. 5 is a view showing a newly discovered electrostatic discharge destruction mechanism of a gate insulating film of an interface circuit provided between circuits that differ in power supply system.

FIG. 6 is a circuit diagram illustrative of an example of a specific configuration of the main portion of an integrated circuit device according to the invention.

FIG. 7 is a cross-sectional view showing the device configuration of some circuits (i.e., second circuit block and input buffer which forms an interface circuit) shown in FIG. 6.

FIG. 8 is a view showing the circuit configuration of an electrostatic discharge protection circuit (bidirectional diodes) inserted between a first low-potential power supply and a second low-potential power supply.

FIG. 9 is a cross-sectional view showing the device structure of the electrostatic discharge protection circuit (bidirectional diodes) shown in FIG. 8.

FIG. 10 is a cross-sectional view showing another example of the device structure of the electrostatic discharge protection circuit (bidirectional diodes) shown in FIG. 8.

FIG. 11 is a block diagram showing the configuration of a driver IC (and part of a liquid crystal panel) of a liquid crystal display device to which the invention is applied.

FIGS. 12A to 12C are views illustrative of a specific configuration and operation of a high-speed interface (I/F) circuit.

FIGS. 13A and 13B are circuit diagrams showing modifications of the configuration of a physical layer included in a high speed interface (I/F) circuit.

FIG. 14 is a view showing a layout example of a driver IC of a liquid crystal display device.

FIG. 15 is a view showing the type of circuit (classification depending on breakdown voltage) used in the driver IC of the liquid crystal display device shown in FIG. 10.

FIGS. 16A and 16B are cross-sectional views showing the device configuration (triple-well structure) of a first circuit block and a second circuit block.

FIGS. 17A and 17B are views showing a method of forming a substrate potential stabilization P+ region (second-conductivity-type diffusion region).

### DETAILED DESCRIPTION OF THE EMBODIMENT

Several aspects of the invention may improve electrostatic discharge protection of an integrated circuit device including an interface circuit provided between different power supply systems by a simple configuration, for example.

(1) According to one embodiment of the invention, there is provided an integrated circuit device comprising:

a first circuit block;

a second circuit block that operates using a power supply system differing from that of the first circuit block; and

an interface circuit provided between the first circuit block and the second circuit block,

gate insulating films of some or all of a plurality of insulated gate transistors that form the interface circuit having a thickness larger than a thickness of a gate insulating film of at least one insulated gate transistor included in at least one of the first circuit block and the second circuit block.

This configuration effectively improves electrostatic discharge protection of the interface circuit without providing an additional circuit configuration.

(2) In the integrated circuit device,

the interface circuit may include at least one of a first buffer circuit and a second buffer circuit;

the first buffer circuit may include a first output buffer that buffers a signal from the first circuit block and outputs the buffered signal to a first signal path, and a first input buffer that buffers a signal transmitted from the first output buffer through the first signal path and supplies the buffered signal to the second circuit block;

the second buffer circuit may include a second output buffer that buffers a signal from the second circuit block and outputs the buffered signal to a second signal path, and a second input buffer that buffers a signal transmitted from the second output buffer through the second signal path and supplies the buffered signal to the first circuit block;

the first output buffer and the second input buffer may operate at a power supply voltage of the first circuit block;

the first input buffer and the second output buffer may operate at a power supply voltage of the second circuit block; and

gate insulating films of insulated gate transistors that form the first input buffer and the second input buffer may have a thickness larger than a thickness of a gate insulating film of at least one insulated gate transistor that forms at least one of the first circuit block and the second circuit block.

The interface circuit includes at least one of the first buffer circuit and the second buffer circuit. The first buffer circuit or the second buffer circuit includes an input buffer and an output buffer which make a pair. The input buffer and the output buffer which make a pair are connected through a signal path. The input buffer and the output buffer which make a pair differ in power supply voltage. For example, when the output buffer receives a signal from the first circuit block, the output buffer operates at the same power supply voltage as the first circuit block. When the input buffer supplies a signal to the second circuit block, the input buffer operates at the same power supply voltage as the second circuit block.

In the interface circuit having such a configuration, the gate insulating films of the transistors that form the input buffer have a thickness larger than the thickness of the gate insulating film of at least one transistor that forms at least one of the first circuit block and the second circuit block. Specifically, the first circuit block or the second circuit block necessarily includes a transistor of which the gate insulating film has a thickness smaller than that of the transistor that forms the input buffer included in the interface circuit.

According to the new electrostatic discharge destruction mechanism discovered by the inventors of the invention, an electrostatic surge applied to the power supply terminal partially flows through a signal path (normal signal line) that connects a pair of input/output buffers, whereby the gate insulating film of the transistor that forms the input buffer tends to break.

Specifically, the inventors of the invention found that it is particularly important to improve gate breakdown protection of the input buffer of the interface circuit provided between circuits that differ in power supply system. According to this embodiment, the gate insulating films of the transistors that form the input buffer are formed to have a thickness larger than the thickness of the gate insulating film of the transistor that forms at least one of the first circuit block and the second circuit block. This enables electrostatic discharge protection of the transistors that form the input buffer to be effectively improved without providing an additional circuit configuration.

(3) In the integrated circuit device,

gate insulating films of insulated gate transistors that form the first output buffer and the second output buffer may have a thickness larger than a thickness of a gate insulating film of at least one insulated gate transistor that forms at least one of the first circuit block and the second circuit block.

Specifically, the thickness of the gate insulating film of the transistor that forms the output buffer (first and second output buffers) included in the interface circuit is increased in the same manner as the transistor that forms the input buffer (first and second input buffers). This reasonably improves electrostatic discharge protection of the transistor that forms the output buffer. According to this embodiment, since the input buffer and the output buffer can be formed at the same time using an identical mask, the production process of the interface circuit does not become complicated.

(4) In the integrated circuit device,

the first circuit block may operate using a first high-potential power supply and a first low-potential power supply; the second circuit block may operate using a second high-potential power supply and a second low-potential power supply; and an electrostatic discharge protection circuit for noise blocking and electrostatic discharge protection may be provided between a power supply node connected to the first low-potential power supply and a power supply node connected to the second low-potential power supply.

The above configuration specifies that the electrostatic discharge protection circuit is provided between the low-potential power supplies of the circuits that operate using different power supply systems. The electrostatic discharge protection circuit forms an electrostatic energy (electrostatic surge) discharge path when a positive or negative electrostatic voltage is applied between the first high-potential power supply of the first circuit block (or the second high-potential power supply of the second circuit block) and the second low-potential power supply of the second circuit block (or the first low-potential power supply of the first circuit block), for example.

When only a normal signal path (normal signal line) is provided as an electrostatic surge discharge path in the output buffer and the input buffer that make a pair and operate using different power supply systems, the electrostatic surge necessarily flows from the output-buffer-side high-potential power supply to the input-buffer-side low-potential power supply through the normal signal path. In this case, the entire electrostatic surge energy is directly applied to the gate of the transistor that forms the input buffer.

On the other hand, when the electrostatic discharge protection circuit is provided between the low-potential power supplies, the electrostatic surge applied to the output-buffer-side high-potential power supply can flow toward the input-buffer-side low-potential power supply through the output-buffer-side low-potential power supply and the electrostatic discharge protection circuit. Therefore, the amount of electrostatic current that flows through the normal signal line sufficiently decreases. This reliably prevents destruction of the transistor with improved electrostatic discharge protection due to an increase in the thickness of the gate insulating film.

The electrostatic discharge protection circuit also has a function of blocking transmission of minute noise between the power supply node connected to the first low-potential power supply and the power supply node connected to the second low-potential power supply. This prevents a situation in which a small change in potential at one power supply node is transmitted to the other power supply node. Therefore, interference between the first circuit block and the second circuit block due to noise is prevented.

(5) In the integrated circuit device,

the electrostatic discharge protection circuit may include bidirectional diodes, the bidirectional diodes being formed by connecting at least one first diode and at least one second diode in parallel, a forward direction of the at least one first diode being a direction from the first low-potential power supply to the second low-potential power supply, and a forward direction of the at least one second diode being a direction from the second low-potential power supply to the first low-potential power supply.

The above configuration specifies that the electrostatic discharge protection circuit provided between the first low-potential power supply and the second low-potential power supply is formed of bidirectional diodes in one or more stages. This makes it possible to form an electrostatic discharge path from the first low-potential power supply to the second low-potential power supply and an electrostatic discharge path from the second low-potential power supply to the first low-potential power supply by a simple configuration. Moreover, noise transmission from the first low-potential power supply to the second low-potential power supply and noise transmission from the second low-potential power supply to the first low-potential power supply can be prevented by a simple configuration.

(6) In the integrated circuit device,

the integrated circuit device may further include: a first inter-power-supply protection element provided between a power supply node connected to the first high-potential power supply and a power supply node connected to the first low-potential power supply; and a second inter-power-supply protection element provided between a power supply node connected to the second high-potential power supply and a power supply node connected to the second low-potential power supply.

Since the first inter-power-supply protection element is provided, a discharge path is formed when static electricity is applied between the power supplies of the first circuit block, whereby a surge current can be bypassed. Therefore, the first circuit block can be protected from electrostatic discharge destruction. Likewise, since the second inter-power-supply protection element is provided, a discharge path is formed when static electricity is applied between the power supplies of the second circuit block, whereby a surge current can be bypassed. Therefore, the second circuit block can be protected from electrostatic discharge destruction.

When the first (or second) inter-power-supply protection element is provided, a path that passes through the power supply node connected to the first (or second) high-potential power supply, the first (or second) inter-power-supply protection element, the power supply node connected to the first (or second) low-potential power supply, the electrostatic discharge protection circuit between the power supply node connected to the first low-potential power supply and the power supply node connected to the second low-potential power supply, and the power supply node connected to the second (or first) low-potential power supply is formed as a static electricity discharge path. Therefore, the amount of electrostatic current that leaks to the normal signal path (normal signal line) can be sufficiently reduced when static electricity is applied to the power supply terminal.

(7) In the integrated circuit device,

the first circuit block may be a high-speed interface circuit that transfers data through a serial bus; and

the high-speed interface circuit may include a physical layer circuit that includes an analog circuit, and a logic circuit.

The above statement specifies that the high-speed interface circuit is an example of the first circuit block, and gives an example of the configuration of the high-speed interface circuit.

(8) In the integrated circuit device,

the second circuit block may be a driver logic circuit that generates a display control signal for driving a display device.

The above statement specifies that the invention may be applied to the driver IC of the liquid crystal display device.

(9) In the integrated circuit device,

channel regions of the gate insulating films of the interface circuit that have a thickness larger than the thickness of the gate insulating films of the insulated gate transistors of the first circuit block and the second circuit block may be subjected to a doping process that reduces a threshold value.

The threshold value of the insulated gate transistor can be adjusted by impurity implantation into the channel region, whereby a decrease in operation speed due to an increase in the thickness of the gate insulating film can be compensated for.

(10) In the integrated circuit device,

the integrated circuit device may include a low-voltage circuit region, a medium-voltage circuit region having a breakdown voltage higher than that of the low-voltage circuit region, and a high-voltage circuit region having a breakdown voltage higher than that of the medium-voltage circuit region;

at least part of the first circuit block may be formed in the low-voltage circuit region;

at least part of the second circuit block may be formed in the low-voltage circuit region; and

the first input buffer and the second input buffer of the interface circuit may be formed in the medium-voltage circuit region.

The invention may be easily applied to an IC including circuits that differ in breakdown voltage by changing a mask. Specifically, the medium-voltage transistors of the interface circuit (i.e., transistors of which the thickness of the gate insulating film is increased) can be formed when forming transistors in other medium-voltage circuit regions. Therefore, the production process can be used in common.

(11) The integrated circuit device may further include a data line driver block that drives a data line of the display device, the data line driver block being formed in the medium-voltage circuit region.

The above statement specifies that the data line driver block is an example of the circuit block formed in the medium-voltage circuit region.

(12) The integrated circuit device may further include a scan line driver block that drives a scan line of a display device, the scan line driver block being formed in the high-voltage circuit region.

The above statement specifies that the scan line driver block is an example of the circuit block formed in the high-voltage circuit region.

(13) The integrated circuit device may include:

a power supply circuit block formed in the high-voltage circuit region and the medium-voltage circuit region; and

a grayscale voltage generation circuit formed in the medium-voltage circuit region.

The above statement specifies that the power supply circuit block is preferably formed in the high-voltage circuit region and the medium-voltage circuit region, and that another example of the circuit formed in the medium-voltage circuit region includes the grayscale voltage generation circuit (circuit that generates multi-valued reference grayscale voltages corresponding to grayscales necessary for implementing a desired grayscale display).

(14) In the integrated circuit device,

a first-conductivity-type transistor that forms the first circuit block may be formed in a second-conductivity-type well;

a second-conductivity-type transistor that forms the first circuit block may be formed in a first first-conductivity-type well, the first first-conductivity-type well being formed in a second-conductivity-type substrate to enclose the second-conductivity-type well;

a first-conductivity-type transistor that forms the second circuit block may be formed in the second-conductivity-type substrate; and

a second-conductivity-type transistor that forms the second circuit block may be formed in a second first-conductivity-type well that differs from the first first-conductivity-type well for the first circuit block.

According to this embodiment, a triple-well structure is employed. The circuits according to the invention are formed on the assumption that the first circuit block and the second circuit block operate using different power supply systems. Circuits that operate using different power supply systems can be reasonably formed in a compact manner using the triple-well structure. Specifically, the triple-well structure enables the transistors of the first circuit block and the transistors of the second circuit block to be electrically separated by a barrier (diode) formed between the second-conductivity-type substrate and the first first-conductivity-type well. This makes it possible to adjacently provide the first circuit block and the second circuit block which are electrically separated.

(15) According to another embodiment of the invention, there is provided an electronic instrument comprising:

one of the above integrated circuit devices; and

a display device driven by the integrated circuit device.

The above integrated circuit device has a simple configuration, has effectively improved electrostatic discharge destruction protection, and exhibits high reliability. Therefore, the reliability of the electronic instrument including the integrated circuit device is also improved.

As described above, several embodiments of the invention can improve electrostatic discharge protection of an integrated circuit device including an interface circuit provided between different power supply systems by a simple configuration, for example. Therefore, the reliability of the IC is improved.

Embodiments of the invention are described below. Note that the embodiments described below do not in any way limit the scope of the invention defined by the claims laid out herein. Note that all elements of the embodiments described below should not necessarily be taken as essential requirements for the invention.

Example of Basic Configuration of Integrated Circuit Device According to the Invention

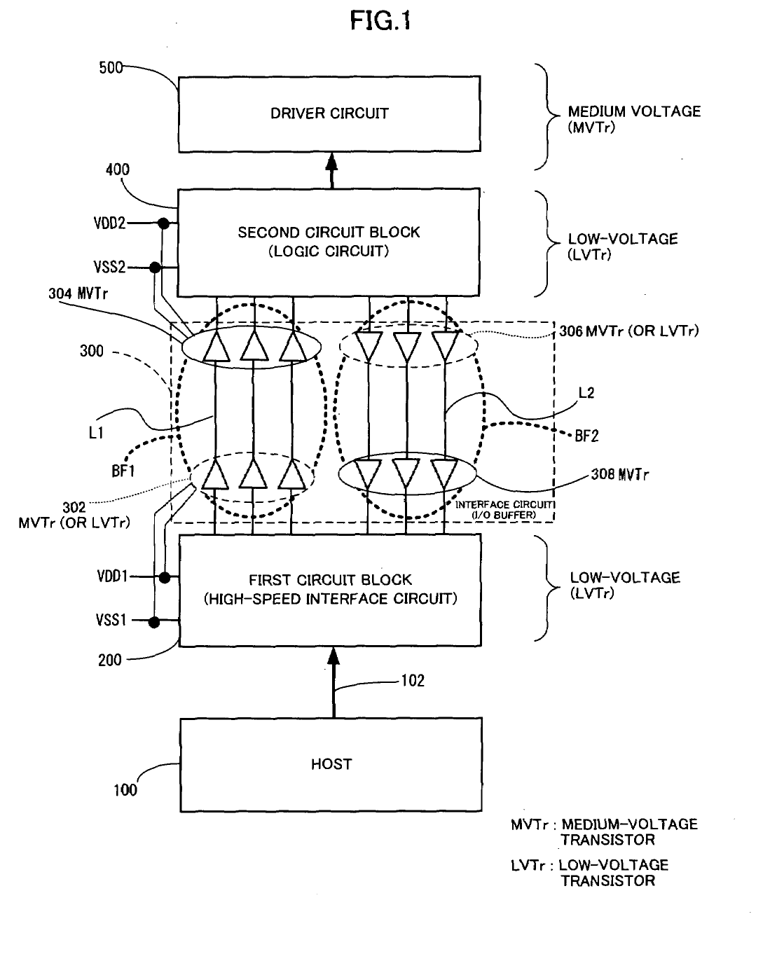

FIG. 1 is a view showing an example of the basic configuration of an integrated circuit device according to the invention. The integrated circuit device shown in FIG. 1 includes a first circuit block (e.g., high-speed interface circuit) 200 which receives an image signal (grayscale data) or a control signal transmitted from a host (e.g., host computer which controls the display operation of a liquid crystal display device) 100 via a serial communication line, a second circuit block 400 (e.g., logic circuit block) which operates using a power supply system differing from that of the first circuit block 200, an interface circuit (hereinafter may be referred to as “I/O buffer”) 300 provided between the first circuit block 200 and the second circuit block 400 (i.e., provided between circuits that differ in power supply system), and a driver circuit (e.g., data line driver circuit of a liquid crystal display device) 500 of which the operation is controlled by the second circuit block (e.g., logic circuit) 400.

The first circuit block 200 operates using a first high-potential power supply VDD1 and a first low-potential power supply VSS1. The second circuit block 400 operates using a second high-potential power supply VDD2 and a first low-potential power supply VSS2.

In FIG. 1, the first circuit block 200 and the second circuit block 400 are low-voltage circuits (e.g., 1.8 V circuits) including a low-voltage transistor (LVTr). Note that the configuration of the integrated circuit device is not limited to this example. Only one of the first circuit block 200 and the second circuit block 400 may be a low-voltage circuit. Only some transistors of the first circuit block 200 or the second circuit block 400 may be low-voltage transistors.

The following example utilizes an insulated gate transistor (MOS transistor: including a metal-insulator-metal (MIS) transistor). The insulated gate transistor may be simply referred to as a transistor.

The interface circuit (I/O buffer) 300 (provided between circuits that differ in power supply system) includes a first buffer circuit BF1 and a second buffer circuit BF2. The first buffer circuit BF1 includes a first output buffer 302 which receives a signal from the first circuit block 200, and a first input buffer 304 which receives a signal from the first output buffer 302.

The first output buffer 302 and the first input buffer 304 make up a pair of input/output buffers. The first buffer circuit BF1 is formed of the output buffer 302 and the input buffer 304 which make up a pair. The pair of input/output buffers (302 and 304) are connected through a normal signal path (normal signal line) L1.

The first output buffer 302 buffers a signal from the first circuit block 200, and outputs the signal to the normal signal path (normal signal line) L1. The first input buffer 304 buffers the signal transmitted from the output buffer 302 through the normal signal path (normal signal line) L1, and supplies the signal to the second circuit block 400.

The first output buffer 302 operates at the same power supply voltage as the first circuit block 200. The first input buffer 304 operates at the same power supply voltage as the second circuit block 400. Specifically, the first output buffer 302 operates using the first high-potential power supply VDD1 and the first low-potential power supply VSS1. The first input buffer 304 operates using the second high-potential power supply VDD2 and the first low-potential power supply VSS2.

The second buffer circuit BF2 includes a second output buffer 306 which receives a signal from the second circuit block 400, and a second input buffer 308 which receives a signal transmitted from the second output buffer 306 through a second signal path (L2).

The second output buffer 306 and the second input buffer 308 make up a pair of input/output buffers. The second buffer circuit BF2 is formed of the output buffer 306 and the input buffer 308 which make up a pair. The pair of input/output buffers (306 and 308) are connected through the normal signal path (normal signal line) L2.

The output buffer 306 buffers a signal from the second circuit block 400, and outputs the signal to the normal signal path (normal signal line) L2. The input buffer 308 buffers the signal transmitted from the output buffer 302 through the normal signal path (normal signal line) L2, and supplies the signal to the first circuit block 200.

The second output buffer 306 operates at the same power supply voltage as the second circuit block 400. The second input buffer 308 operates at the same power supply voltage as the first circuit block 200. Specifically, the second output buffer 306 operates using the second high-potential power supply VDD2 and the second low-potential power supply VSS2. The second input buffer 308 operates using the first high-potential power supply VDD1 and the first low-potential power supply VSS1.

The first buffer circuit BF1 and the second buffer circuit BF2 are provided in FIG. 1. Note that only one of the first buffer circuit BF1 and the second buffer circuit BF2 may be provided. Specifically, both of the pair of input/output buffers (302 and 304) and the pair of input/output buffers (306 and 308) are not necessarily provided. This means that at least one of the first buffer circuit BF1 and the second buffer circuit BF2 is provided.

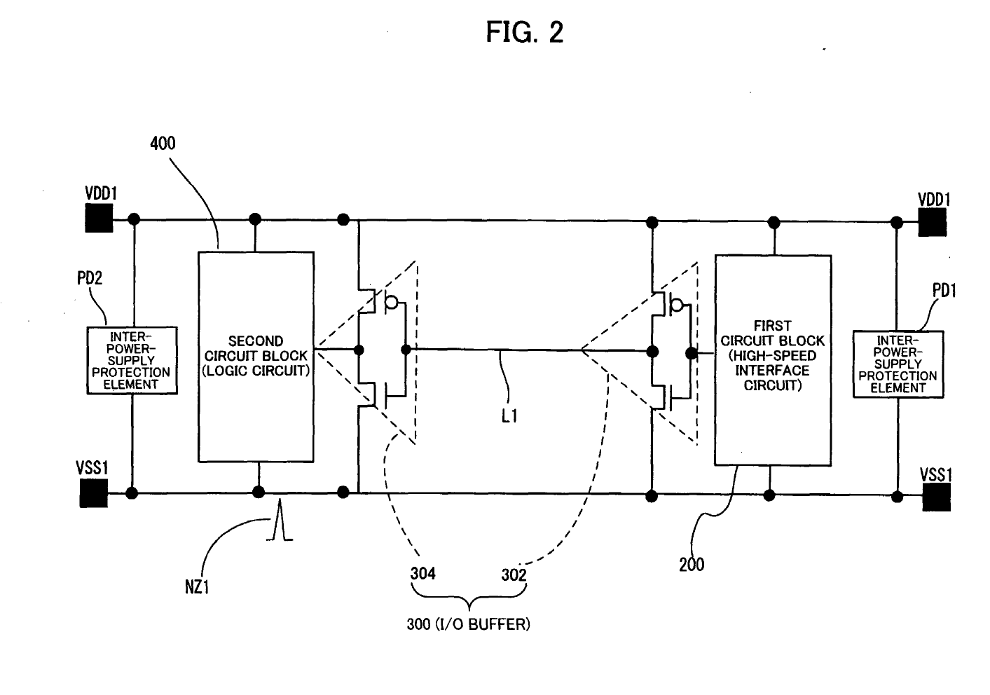

Note that a power supply protection circuit (omitted in FIG. 1) is provided between the power supplies. An electrostatic discharge protection circuit for noise blocking and electrostatic discharge protection is provided between the low-potential power supplies in different power supply systems (described later with reference to FIGS. 2 to 6).

The interface circuit 300 (provided between circuits that differ in power supply system) is normally formed of a low-voltage circuit (e.g., 1.8 V circuit), as described with reference to the related-art technology. In the integrated circuit device shown in FIG. 1, some or all of the transistors which form the interface circuit 300 (provided between circuits that differ in power supply system) are formed of medium-voltage transistors (MVTr) which are higher in breakdown voltage than low-voltage transistors (LVTr).

The thickness of the gate insulating film of the medium-voltage transistor (MVTr) is set to be larger than the thickness of the gate insulating film of the low-voltage transistor (LVTr). Therefore, the gate breakdown voltage of the medium-voltage transistor is higher than that of the low-voltage transistor.

For example, when the thickness of the gate insulating film of a high-voltage transistor (HVTr) is about 1000 angstroms, the thickness of the gate insulating film of a medium-voltage transistor (MVTr) is about 150 angstroms, and the thickness of the gate insulating film of a low-voltage transistor (LVTr) is about 50 angstroms, for example. Note that these values are only examples.

The expression “some or all of the transistors which form the interface circuit 300 are formed of medium-voltage transistors (MVTr)” used herein means that the interface circuit 300 may include at least two types of transistors which differ in breakdown voltage (e.g., low-voltage transistor (LVTr) and medium-voltage transistor (MVTr)) in combination, but necessarily includes high-breakdown-voltage transistors such as medium-voltage transistors (MVTr).

According to the newly discovered electrostatic discharge destruction mechanism revealed by the inventors of the invention, destruction of the gate insulating films of the transistors which form the first and second input buffers (304 and 308) easily occurs.

In this embodiment, it is particularly important to employ medium-voltage transistors (MVTr) as the transistors which form the first and second input buffers (304 and 308) to increase the gate breakdown voltage. This effectively improves gate breakdown protection without providing an additional circuit.

It is also useful to increase the thickness of the gate insulating films of the transistors which form the first and second output buffers (302 and 306) included in the interface circuit 300 in the same manner as the transistors which form the first and second input buffers (304 and 308).

This reasonably improves electrostatic discharge protection of the transistors which form the output buffers (302 and 306), whereby electrostatic discharge protection of the entire interface circuit 300 is improved. In this case, since the transistors which form the first and second input buffers (304 and 308) and the transistors which form the first and second output buffers (302 and 306) can be simultaneously formed using an identical mask, the production process of the interface circuit 300 does not become complicated.

The low-voltage transistors and the high-breakdown-voltage transistors (medium-voltage transistors) may be appropriately and selectively used as the transistors which form the first and second output buffers (302 and 306) depending on the circuit specification (e.g., breakdown voltage and operating speed), the characteristics of the available production process, the circuit operating conditions, and the like.

Destruction of the gate insulating films of the transistor which form the interface circuit 300 due to an electrostatic pulse can be reasonably prevented without providing an additional configuration by forming some or all of the transistors which form the interface circuit 300 using medium-voltage transistors (MVTr: i.e., transistors which are higher in breakdown voltage than the transistors (LVTr) having the lowest breakdown voltage among the transistors which form at least one of the first circuit block and the second circuit block 200 and 400), for example. Therefore, the reliability of the integrated circuit device can be improved.

The integrated circuit device shown in FIG. 1 includes the circuit (driver circuit 500) which utilizes medium-voltage transistors (MVTr). Therefore, the interface circuit 300 may be formed when forming the driver circuit 500. This enables the interface circuit 300 to be reasonably formed using medium-voltage transistors (MVTr).

The reasons that destruction of the gate insulating films of the interface circuit 300 easily occurs (new electrostatic discharge destruction mode) are given below. The following reasoning was made by the inventors of the invention before completion of the invention. A specific configuration example of the main portion of the integrated circuit device according to the invention was conceived during the reasoning process.

New Electrostatic Discharge Destruction Mode

### (1) First Example

FIG. 2 is a circuit diagram showing a configuration example of the interface circuit (provided between circuits that differ in power supply system) according to a first example. In FIG. 2, the output buffer 302 and the input buffer 304 shown in FIG. 1 are collectively referred to as the I/O buffer 300 for convenience. This reference is appropriately used in the following description. The I/O buffer 300 is the same as the interface circuit 300.

In the circuit shown in FIG. 2, the first circuit block 200, the second circuit block 400, and the I/O buffer 300 (including the input buffer 302 and the output buffer 304) operate using common power supply voltages (VDD1 and VSS1).

Inter-power-supply protection elements (PD1 and PD2) formed of a diode or a thyristor are provided between the first high-potential power supply (VDD1) and the first low-potential power supply (VSS1). For example, the inter-power-supply protection elements (PD1 and PD2) are formed of Zener diodes.

When an electrostatic pulse is applied between the power supplies, the inter-power-supply protection elements (PD1 and PD2) are turned ON to form discharge paths so that electrostatic energy can be bypassed. This prevents electrostatic discharge destruction of the first circuit block and the second circuit block (200 and 400).

However, since the power supply lines are used in common in the circuit shown in FIG. 2, power supply noise (NZ1) produced by the second circuit block 400 may adversely affect the operation of the first circuit block 200 (particularly the operation of the analog circuit), for example.

### (2) Second Example

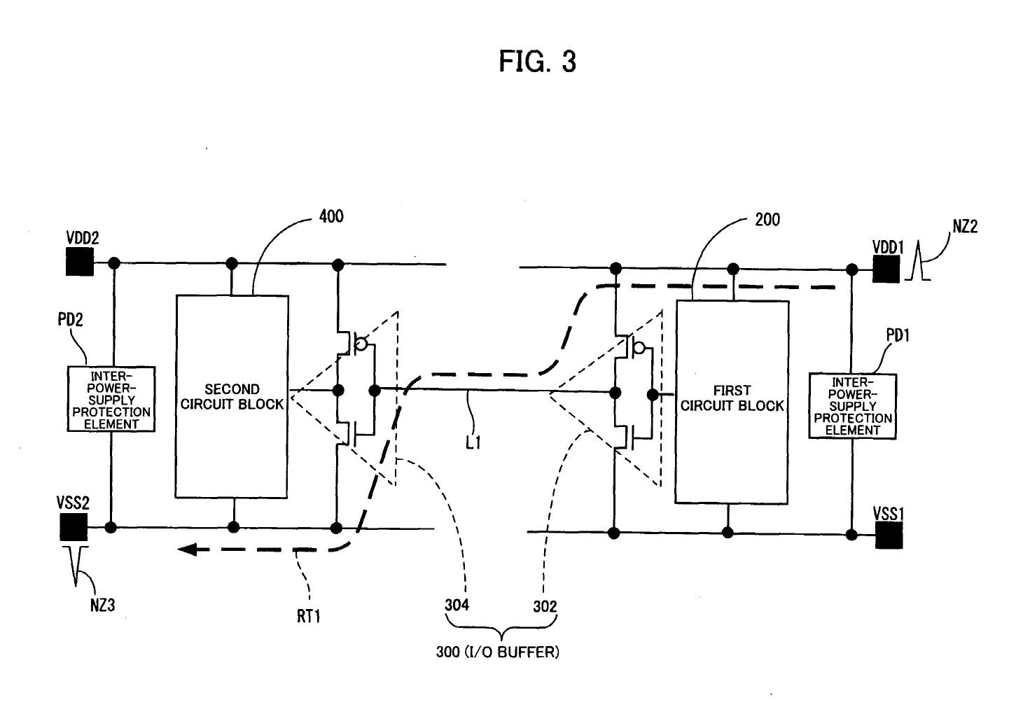

FIG. 3 is a circuit diagram showing a configuration example of the interface circuit (provided between circuits that differ in power supply system) according to a second example. In FIG. 3, the power supplies of the first circuit block 200 are completely separated from the power supplies of the second circuit block 400. Therefore, an adverse effect of power supply noise between the circuits does not occur, differing from FIG. 2.

However, when a positive electrostatic pulse (NZ2) is applied to a terminal connected to the first high-potential power supply (VDD1) and a negative electrostatic pulse (NZ3) is applied to a terminal connected to the second low-potential power supply (VSS2), a transient current (large amount of instantaneous current) due to static electricity flows through the signal line L1 along a route (RT1) indicated by a bold dotted line in FIG. 3. In this case, the gate insulating films of PMOS and NMOS transistors (particularly the NMOS transistor on the lower side) which form the input buffer 304 may break.

It is considered that a situation in which a positive electrostatic pulse (NZ2) is applied to the terminal connected to the first high-potential power supply (VDD1) and a negative electrostatic pulse (NZ3) is applied to the terminal connected to the second low-potential power supply (VSS2) rarely occurs in practice. However, since the power supply terminal is connected to the outside of the integrated circuit device, application of such an external electrostatic surge could possibly occur. It is necessary to take measures to prevent electrostatic discharge destruction assuming all possible situations, taking the importance of such prevention into consideration. Therefore, it is also important to conduct an electrostatic discharge test under the above-mentioned severe conditions.

### (3) Third Example

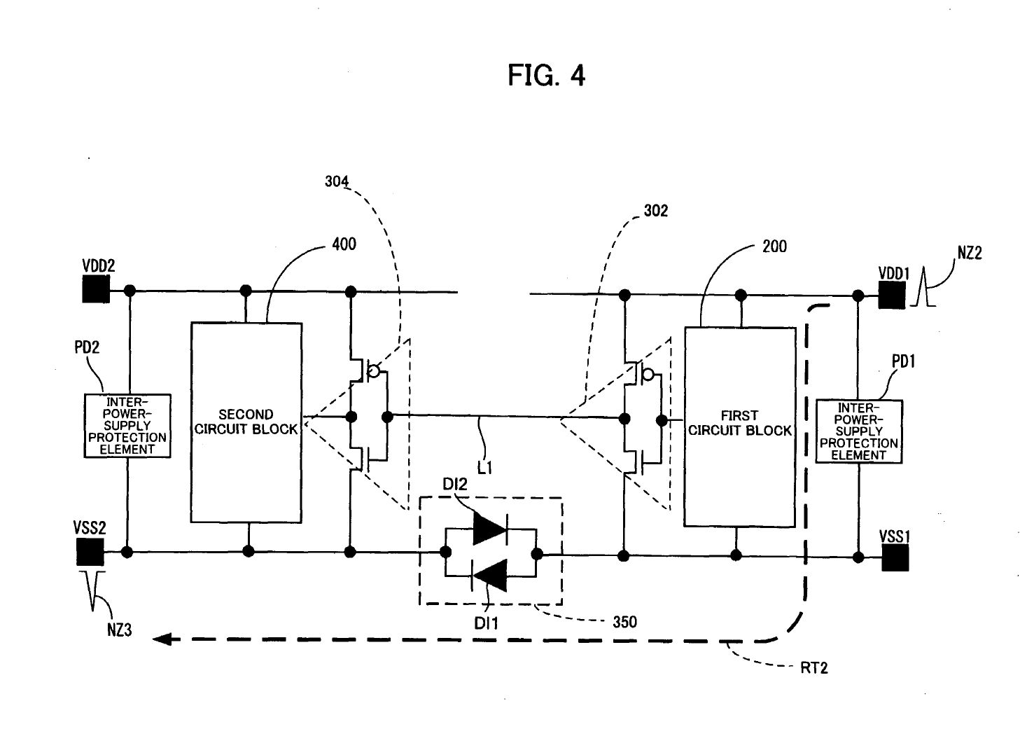

FIG. 4 is a circuit diagram showing a configuration example of the interface circuit (provided between circuits that differ in power supply system) according to a second example.

In FIG. 4, an electrostatic discharge protection circuit 350 including bidirectional diodes (DI1 and DI2) is provided between the first low-potential power supply and the second low-potential power supply (VSS1 and VSS2). The first diode (DI1) is a PN diode of which the forward direction is the direction from the first circuit block 200 to the second circuit block 400 (the first diode (DI1) is not limited thereto), and the second diode (DI2) is a PN diode of which the forward direction is the direction from the second circuit block 400 to the first circuit block 200 (the second diode (DI2) is not limited thereto).

According to this configuration, when a positive electrostatic pulse (NZ2) is applied to the terminal connected to the first high-potential power supply (VDD1) and a negative electrostatic pulse (NZ3) is applied to the terminal connected to the second low-potential power supply (VSS2), the first diode DI1 is turned ON so that a discharge path is formed along a bypass route RT2 indicated by a bold dotted line in FIG. 4.

Therefore, a transient current (large amount of instantaneous current) due to static electricity is discharged through the bypass route RT2. Since each of the bidirectional diodes (DI1 and DI2) has a forward voltage of about 0.6 V, transmission of minute power supply noise (ground noise) is prevented due to the forward voltage which serves as a barrier. Therefore, interference between the first circuit block 200 and the second circuit block 400 due to noise is prevented.

According to the circuit shown in FIG. 4, destruction of the gate insulating films of the transistors which form the input buffer 304 should be prevented in this manner.

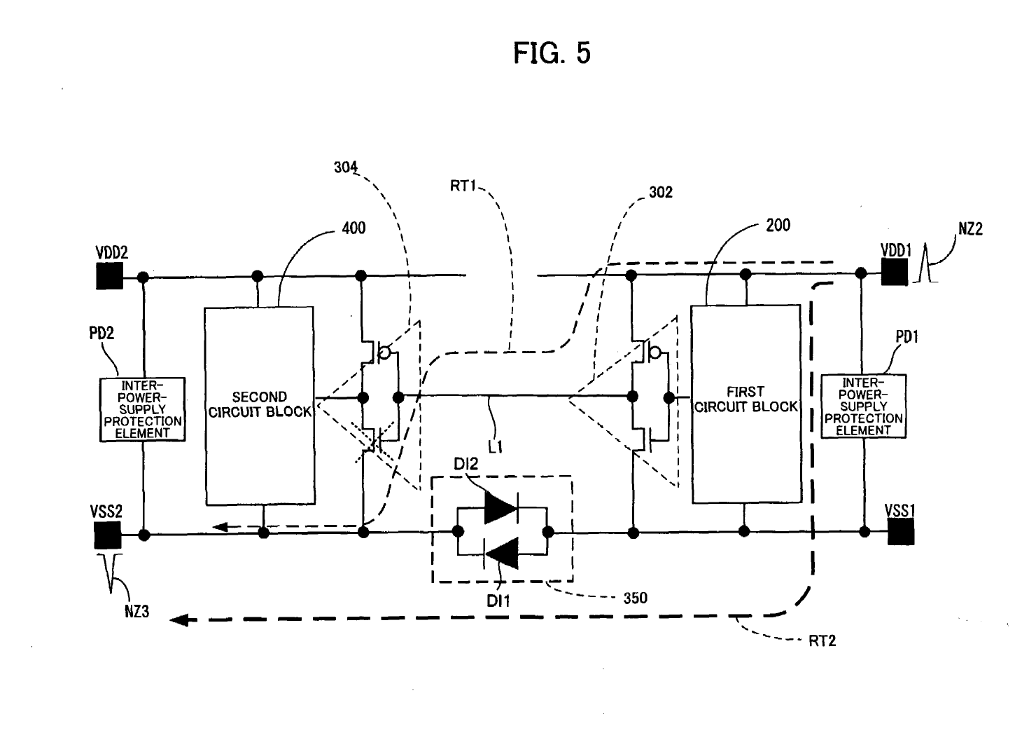

FIG. 5 is a view showing a newly discovered electrostatic discharge destruction mechanism of the gate insulating film of the interface circuit provided between circuits that differ in power supply system. It was found that electrostatic surge energy partially flows through the normal signal line L1 along a route RT1 indicated by a dotted line in FIG. 5 in the actual situation. Specifically, electrostatic surge energy applied to the power supply terminal does not entirely flow through the bypass route, but partially leaks to the normal signal path (normal signal line) L1.

Therefore, destruction (marked with “x” indicated by a dotted line in FIG. 5) of the gate insulating films of the transistors (particularly the NMOS transistor on the lower side) which form the input buffer 304 may occur in the same manner as in FIG. 4. It is estimated that the NMOS transistor on the lower side easily breaks because the source of the NMOS transistor is connected to the low-potential power supply VSS2 (ground).

Specifically, the reasoning by the inventors of the invention revealed that electrostatic discharge destruction cannot be completely prevented by merely providing the electrostatic discharge protection circuit 350 including the bidirectional diodes (DI1 and DI2) shown in FIG. 4.

### First Embodiment

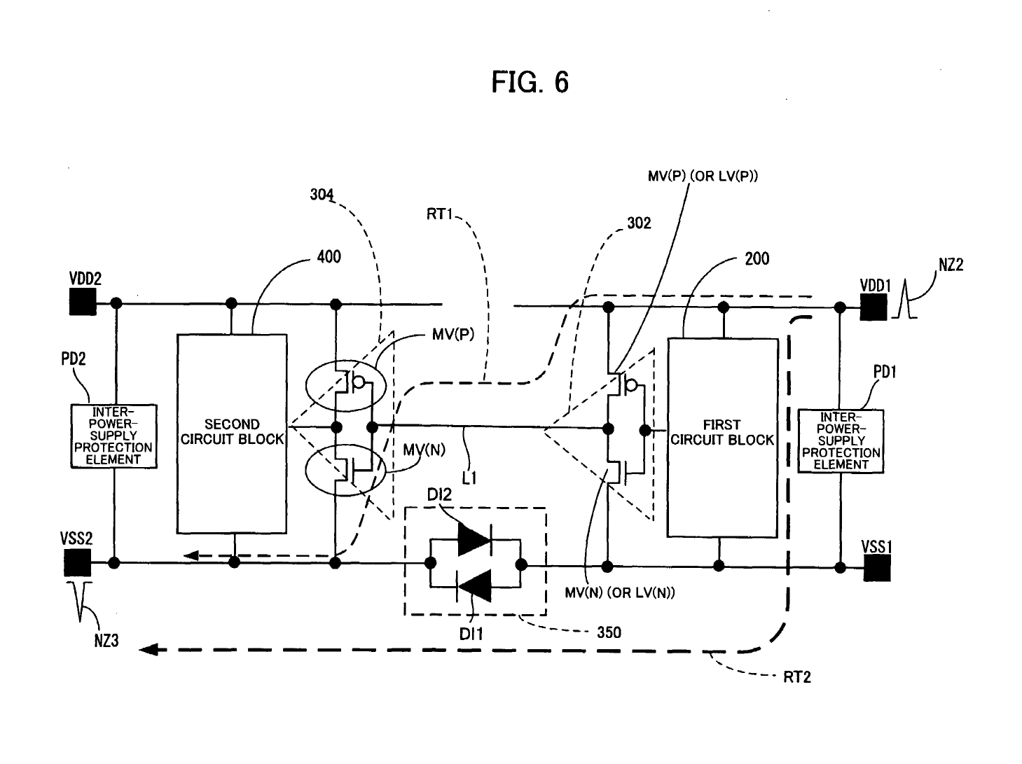

FIG. 6 is a circuit diagram illustrative of a specific configuration of the main portion of the integrated circuit device according to the invention. In view of the above reasoning, the invention utilizes medium-voltage transistors (MVTr) as the PMOS transistor and the NMOS transistor of the input buffer 304 susceptible to electrostatic discharge destruction instead of low-voltage transistors (LVTr), as shown in FIG. 6. Specifically, a related-art circuit design method necessarily utilizes low-voltage transistors (LVTr) as the PMOS transistor and the NMOS transistor of the input buffer 304, giving priority to the operating speed. On the other hand, this embodiment utilizes transistors having a higher breakdown voltage (i.e., medium-voltage transistors MVTr) as the PMOS transistor and the NMOS transistor of the input buffer 304, giving priority to prevention of electrostatic discharge destruction of the gate insulating films.

The operating speed decreases to some extent as a result of giving priority to protection of the gate insulating films. However, a decrease in operating speed can be compensated for by adjusting the threshold voltage utilizing channel ion implantation, for example (described later).

In FIG. 6, the PMOS transistor of the input buffer 304 is formed of a medium-voltage transistor (MV(P)), and the NMOS transistor is similarly formed of a medium-voltage transistor (MV(N)).

For example, when the thickness of the gate insulating film of the low-voltage transistor (LVTr) is about 50 angstroms and the thickness of the gate insulating film of the medium-voltage transistor (MVTr) is about 150 angstroms, the gate breakdown voltage of the medium-voltage transistor (MVTr) is equal to or higher than a value twice the gate breakdown voltage of the low-voltage transistor (LVTr).

Therefore, even if an electrostatic pulse partially leaks to the normal signal line L1, as shown in FIG. 6, there is very little chance that the gate insulating film will break.

In FIG. 6, the transistors which form the output buffer 302 are also formed of medium-voltage transistors (MV(P) and MV(N)) in order to improve electrostatic discharge protection. Note that the transistors which form the output buffer 302 may also be formed of low-voltage transistors (LV(P) and LV(N)). The medium-voltage transistors or the low-voltage transistors may be appropriately selected (optimized) depending on the circuit specification, the process conditions, and the like.

Although the above description has been given taking an example in which positive static electricity is applied to the first high-potential power supply (VDD1) and negative static electricity is applied to the second low-potential power supply (VSS2), the same description applies to the case where positive static electricity is applied to the second high-potential power supply (VDD2) and negative static electricity is applied to the first low-potential power supply (VSS1). In this case, the input/output buffers (302 and 304) in the above description may be replaced by the input/output buffers (306 and 308: see FIG. 1).

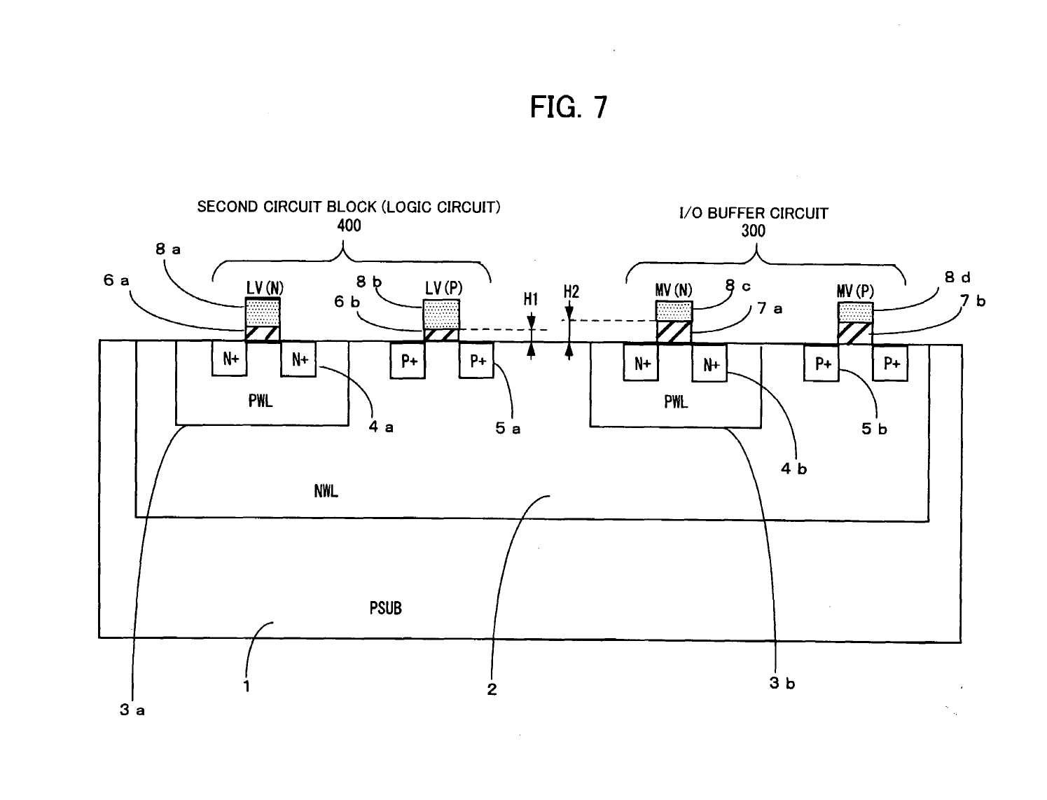

FIG. 7 is a cross-sectional view showing the device configuration of some of the circuits (i.e., the second circuit block and the input buffer which forms the interface circuit) shown in FIG. 6. The integrated circuit device shown in FIG. 7 has a double well structure having an N-well (NWL) 2 formed in a P-type substrate (PSUB) and P-wells (PWL) 3a and 3b formed in the N-well 2.

The second circuit block (logic circuit) 400 (see FIG. 1) shown on the left in FIG. 7 is formed using low-voltage transistors (LVTr).

Specifically, a low-voltage transistor LV(N) includes N+-type impurity regions 4a (source/drain), a gate insulating film (thickness: H1), and a gate layer (formed of polysilicon or the like) 8a.

Likewise, a low-voltage transistor LV(P) includes P+-type impurity regions 5a (source/drain), a gate insulating film 6b (thickness: H1), and a gate layer (formed of polysilicon or the like) 8b.

The transistors (transistors on the right in FIG. 7) which form the input buffer 304 and the like included in the I/O buffer circuit 300 are formed of medium-voltage transistors (MVTr).

Specifically, a medium-voltage transistor MV(N) includes N+-type impurity regions 4b (source/drain), a gate insulating film 7a (thickness: H2 (>H1)), and a gate layer (formed of polysilicon or the like) 8c.

Likewise, a medium-voltage transistor LV(P) includes P+-type impurity regions 5b (source/drain), a gate insulating film 7b (thickness: H2 (>H1)), and a gate layer (formed of polysilicon or the like) 8d.

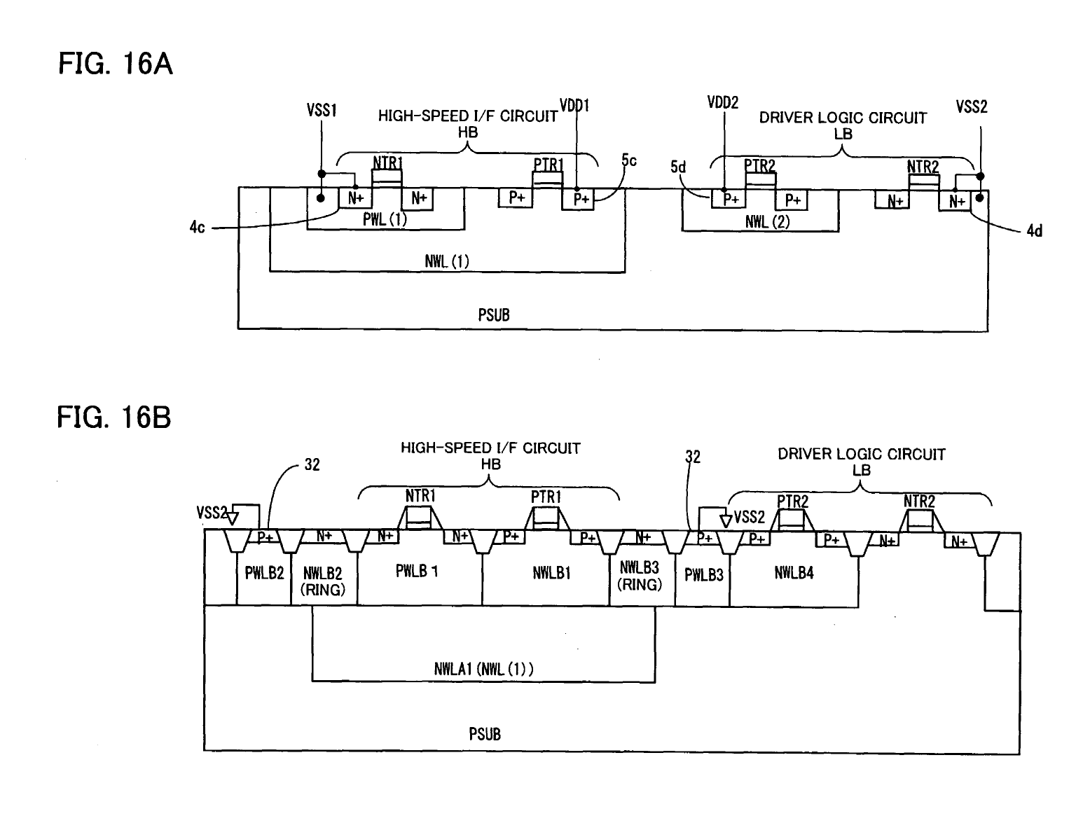

The thickness H1 is about 50 angstroms, and the thickness H2 is about 150 angstroms, for example. Therefore, the medium-voltage transistor MVTr has a gate breakdown voltage equal to or higher than a value twice the gate breakdown voltage of the low-voltage transistor LVTr. An example of a device structure (e.g., triple-well structure) including the first circuit block 200 and the second circuit block 400 is described later with reference to FIG. 16.

Impurity implantation for increasing speed of medium-voltage transistor

The medium-voltage transistor (MVTr) has a disadvantage in terms of the operation speed since the threshold value of the medium-voltage transistor (MVTr) increases due to an increase in the thickness of the gate insulating film. In order to improve the operation speed of the medium-voltage transistor (MVTr), it is effective to implant an impurity which reduces the threshold value into the channel region of each medium-voltage transistor (MV(N) and MV(P)). This makes it possible to achieve a high gate breakdown voltage and a high operation speed.

Configuration of Bidirectional Diodes

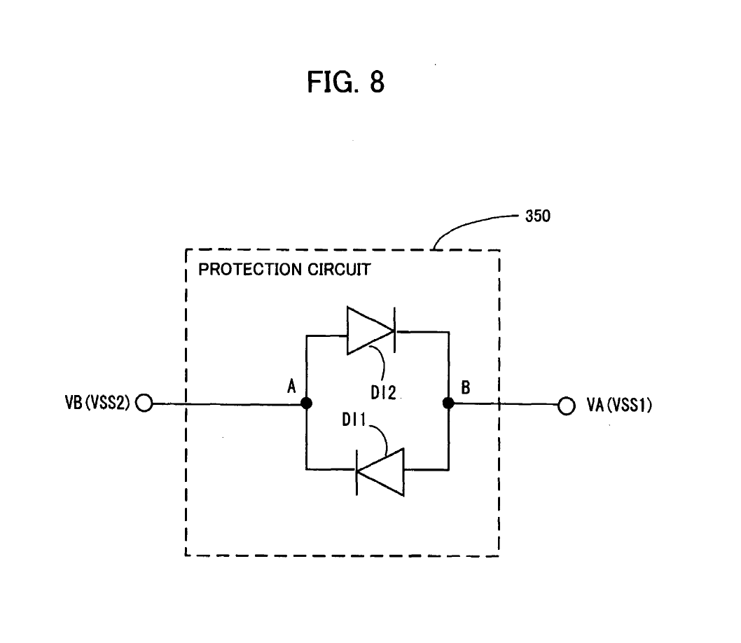

FIG. 8 is a view showing the circuit configuration of the electrostatic discharge protection circuit (bidirectional diodes) inserted between the first low-potential power supply and the second low-potential power supply. In FIG. 8, the potential at a point A (common connection point of the cathode of the diode DI1 and the anode of the diode DI2) is VB (=VSS2), and the potential at a point B (common connection point of the anode of the diode DI1 and the cathode of the diode DI2) is VA (=VSS1).

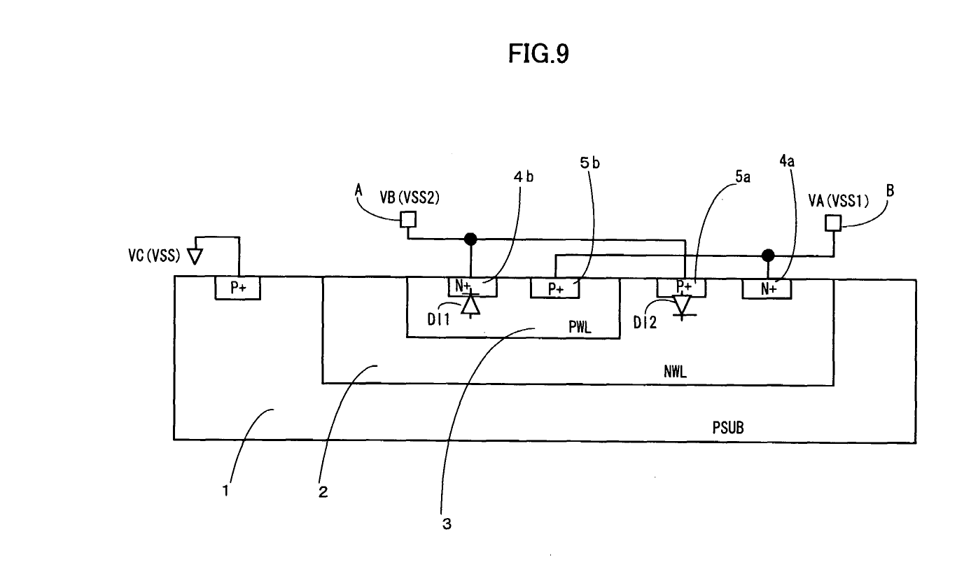

FIG. 9 is a cross-sectional view showing the device structure of the electrostatic discharge protection circuit (bidirectional diodes) shown in FIG. 8. A double-well structure is employed for the device shown in FIG. 9. The double-well structure shown in FIG. 9 may be formed as part of a triple-well structure (structure which facilitates formation of circuit blocks which differ in power supply system) described later, for example. Note that the device structure of the bidirectional diodes is not limited thereto.

As shown in FIG. 9, an N-well (NWL) 2 is formed in a P-type substrate (PSUB) 1, and a P-well (PWL) is formed in the N-well (NWL) 2. An N+ region 4b and a P+ region 5b are formed on the surface of the P-well (PWL) 3. An N+ region 4a and a P+ region 5a are formed on the surface of the N-well (NWL) 2.

As shown in FIG. 9, the first diode (PN diode) DI1 is formed at the junction between the P-well 3 and the N+ region 4b. The second diode (PN diode) DI2 is formed at the junction between the P+ region 5a and the N-well 2.

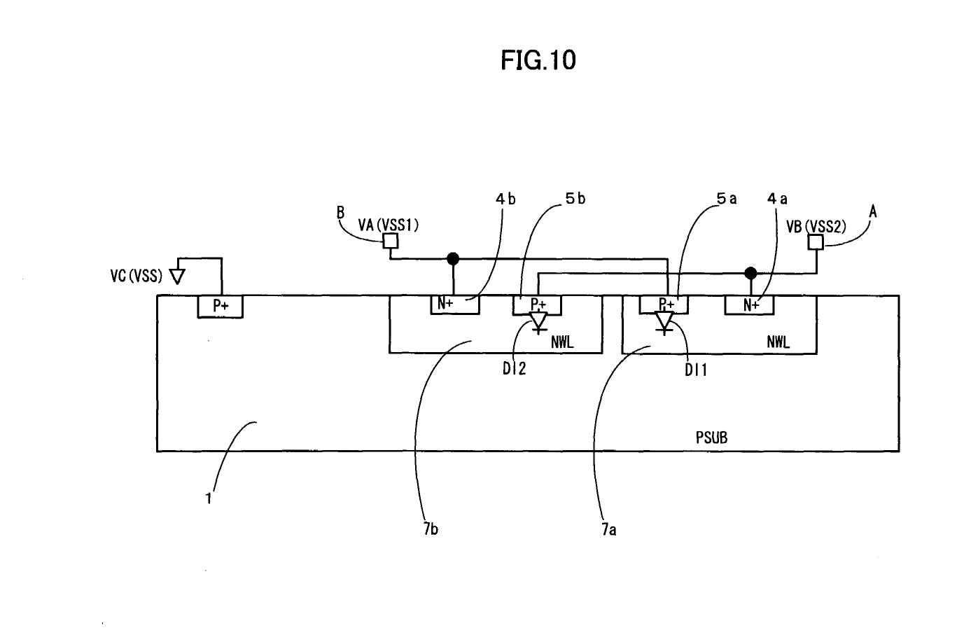

FIG. 10 is a cross-sectional view showing another example of the device structure of the electrostatic discharge protection circuit (bidirectional diodes) shown in FIG. 8. FIG. 10 employs a more simplified structure. Specifically, the first PN diode DI1 is formed at the junction between the P+ region 5a and an N-well (NWL) 7a. The second PN diode DI2 is formed at the junction between the P+ region 5b and an N-well (NWL) 7b. The structure shown in FIG. 10 has an advantage in that load imposed on the production process is reduced.

### Second Embodiment

This embodiment illustrates an example of applying the invention to a driver IC of a liquid crystal display device.

Entire Configuration of Liquid Crystal Display Device

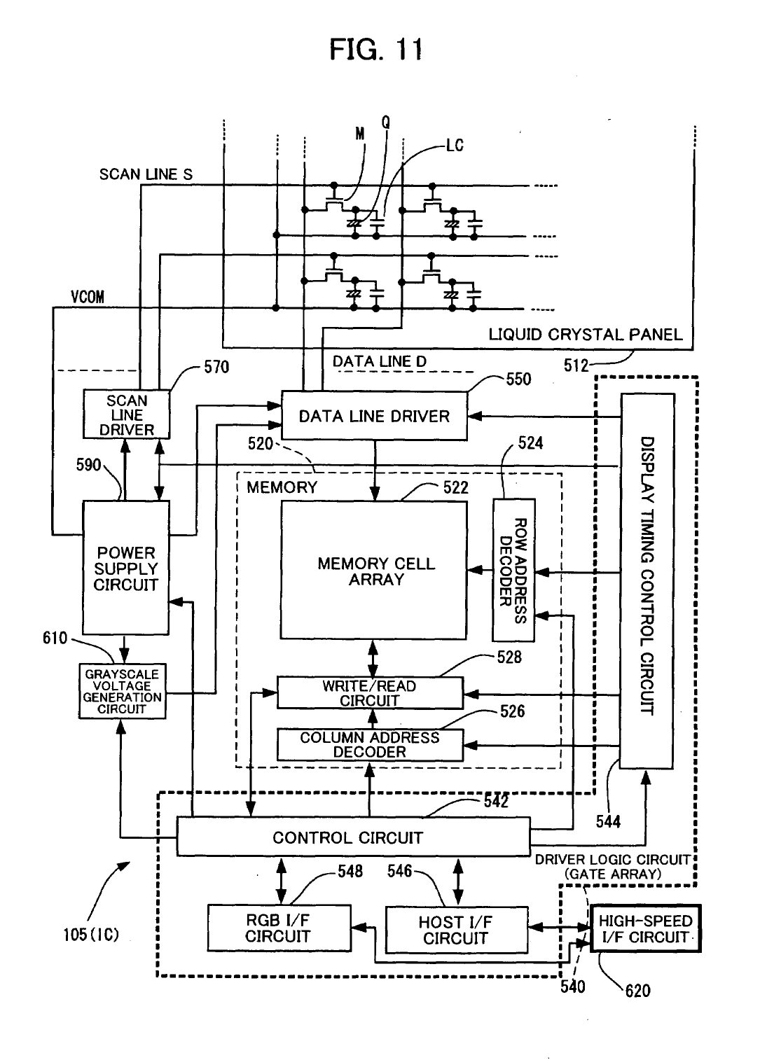

FIG. 11 is a block diagram showing the configuration of a driver IC (and a liquid crystal panel: part of an example of an electronic instrument) of a liquid crystal display device to which the invention is applied.

A liquid crystal panel 512 includes a plurality of data lines (D), a plurality of scan lines (S), and a plurality of pixels specified by the data lines and the scan lines. A display operation is implemented by changing the optical properties of an electro-optical element (liquid crystal element in a narrow sense) in each pixel region. Each pixel includes a transfer switch (M), a storage capacitor (Q), and a liquid crystal element (LC).

The liquid crystal panel 512 is formed using an active matrix type panel utilizing a switching element such as a TFT or a TFD. The liquid crystal panel 512 may be a panel other than the active matrix type panel, or may be a panel (e.g., organic EL panel) other than the liquid crystal panel.

In the driver IC (reference numeral 105) of the liquid crystal display device shown in FIG. 11, the technology according to the invention described with reference to the first embodiment is used for an interface section between a high-speed interface (high-speed I/F circuit) 620 and a driver logic circuit 540 (enclosed by a bold dotted line in FIG. 11).

The configuration of the driver IC (reference numeral 105) of the liquid crystal display device shown in FIG. 11 is described below.

A memory 520 (RAM) stores image data. A memory cell array 522 includes a plurality of memory cells, and stores image data (display data) corresponding to at least one frame (one screen). The memory 520 includes a row address decoder 524 (MPU/LCD row address decoder), a column address decoder 526 (MPU column address decoder), and a write/read circuit 528 (MPU write/read circuit).

A logic circuit 540 (driver logic circuit) generates a display control signal for controlling a display timing or a data processing timing. The logic circuit 540 may be formed by automatic placement and routing (e.g., gate array (G/A)), for example.

A control circuit 542 generates various control signals, and controls the entire device. A display timing control circuit 544 generates a control signal for controlling a display timing, and controls reading of the image data from the memory 520 into the liquid crystal panel 512.

A host interface (I/F) circuit 546 implements a host interface by generating an internal pulse and accessing the memory 520 each time access from a host (MPU) occurs. An RGB I/F circuit 548 implements an RGB interface by writing motion picture RGB data into the memory 520 based on a dot clock signal. The high-speed I/F circuit 620 implements high-speed serial transfer through a serial bus.

A data driver 550 generates a data signal for driving the data line of the liquid crystal panel 512. Specifically, the data driver 550 receives grayscale data (image data) from the memory 520, and receives a plurality of (e.g., 64) grayscale voltages (reference voltages) from a grayscale voltage generation circuit 610. The data driver 550 selects a voltage corresponding to the grayscale data from the received grayscale voltages, and outputs the selected voltage to each data line of the liquid crystal panel 512 as the data signal (data voltage).

A scan driver 570 generates a scan signal for driving the scan line of the liquid crystal panel. A power supply circuit 590 generates various power supply voltages, and supplies the power supply voltages to the data driver 550, the scan driver 570, the grayscale voltage generation circuit 610, and the like. The grayscale voltage generation circuit 610 (gamma correction circuit) generates the grayscale voltage, and outputs the grayscale voltage to the data driver 550.

Specific configuration and operation of high-speed interface (I/F) circuit

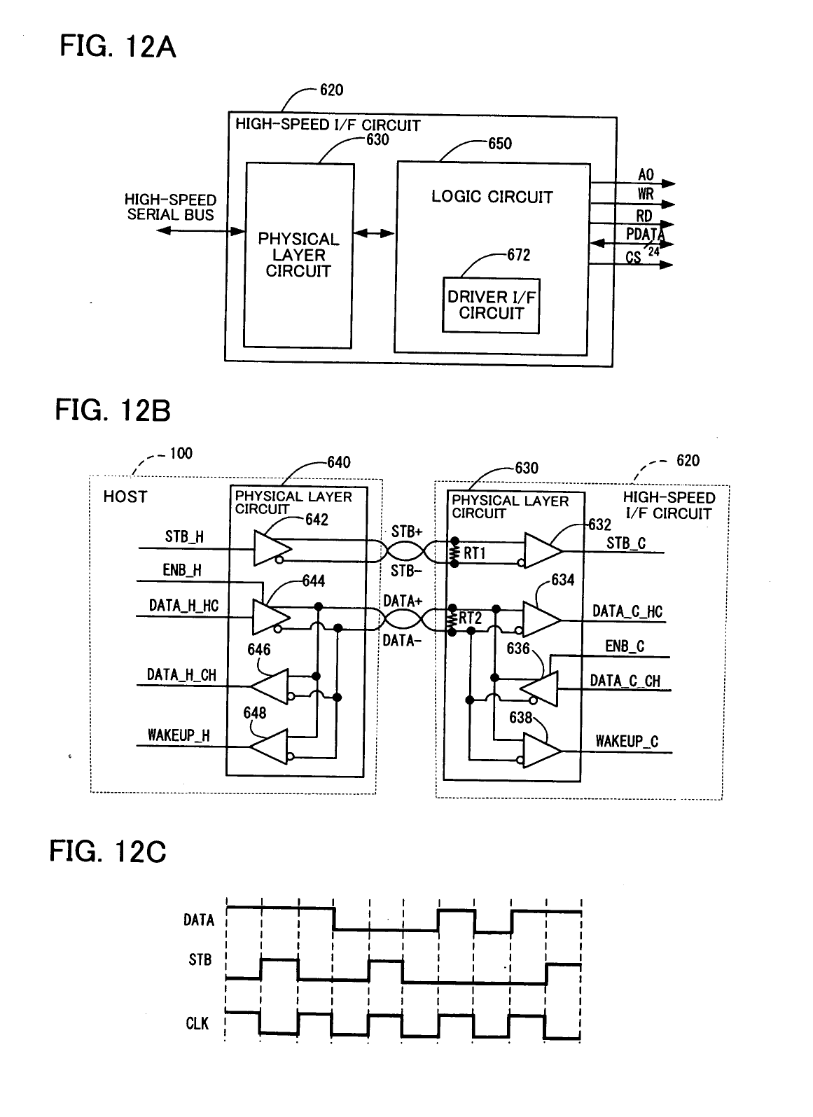

A specific configuration of the high-speed I/F circuit 620 is described below. FIGS. 12A to 12C are views illustrative of a specific configuration and operation of the high-speed interface (I/F) circuit.

FIG. 12A shows a configuration example of the high-speed I/F circuit 620. A physical layer circuit 630 (analog front-end circuit or transceiver) receives or transmits data (a packet) through a serial bus using differential signals (differential data signals, differential strobe signals, and differential clock signals) or the like. Specifically, the physical layer circuit 630 transmits or receives data by current-driving or voltage-driving differential signal lines of the serial bus. The physical layer circuit 630 may include at least one of a receiver circuit which receives data through the serial bus and a transmitter circuit which transmits data through the serial bus.

The serial bus may have a multi-channel configuration. A serial transfer may be performed by single-end transfer. The physical layer circuit 630 may include a high-speed logic circuit. The high-speed logic circuit operates based on a high-speed clock signal corresponding to a serial bus transfer clock signal. Specifically, the physical layer circuit 630 may include a serial/parallel conversion circuit which converts serial data received through the serial bus into parallel data, a parallel/serial conversion circuit which converts parallel data into serial data transmitted through the serial bus, a FIFO, an elasticity buffer, a frequency divider circuit, and the like.

A logic circuit 650 is a logic circuit included in the high-speed I/F circuit 620, and performs a process of a link layer or a transaction layer higher than the physical layer. For example, the logic circuit 650 analyzes a packet received by the physical layer circuit 630 through the serial bus, separates the header and data of the packet, and extracts the header. When transmitting a packet through the serial bus, the logic circuit 650 generates the packet. The logic circuit 650 may be formed by automatic placement and routing (e.g., gate array (G/A)), for example.

The logic circuit 650 includes a driver I/F circuit 672. The driver I/F circuit 672 performs an interface process between the high-speed I/F circuit 620 and an internal circuit (driver logic circuit 540 and host I/F circuit 546 in FIG. 7) of the display driver. Specifically, the driver I/F circuit 672 generates interface signals including an address 0 signal A0 (command/data identification signal), a write signal WR, a read signal RD, a parallel data signal PDATA, a chip select signal CS, and the like, and outputs the interface signals to the internal circuits (other circuit blocks) of the display driver.

FIG. 12B shows a configuration example of the physical layer circuit. In FIG. 12B, a physical layer circuit 640 is provided in a host device, and the physical layer circuit 630 is provided in the display driver. Reference numerals 636, 642, and 644 indicate transmitter circuits, and reference numerals 632, 634, and 646 indicate receiver circuits. Reference numerals 638 and 648 indicate wakeup detection circuits. The host-side transmitter circuit 642 drives signals STB+/−.

The client-side receiver circuit 632 amplifies a voltage across a resistor RT1 generated by driving the signals STB+/−, and outputs a strobe signal STB_C to the circuit in the subsequent stage. The host-side transmitter circuit 644 drives signals DATA+/−. The client-side receiver circuit 634 amplifies a voltage across a resistor RT2 generated by driving the data signals DATA+/−, and outputs a data signal DATA_C_HC to the circuit in the subsequent stage.

As shown in FIG. 12C, the transmitter side generates a strobe signal STB by calculating the exclusive OR of a data signal DATA and a clock signal CLK, and transmits the strobe signal STB to the receiver side through the high-speed serial bus. The receiver side calculates the exclusive OR of the data signal DATA and the strobe signal STB to reproduce the clock signal CLK.

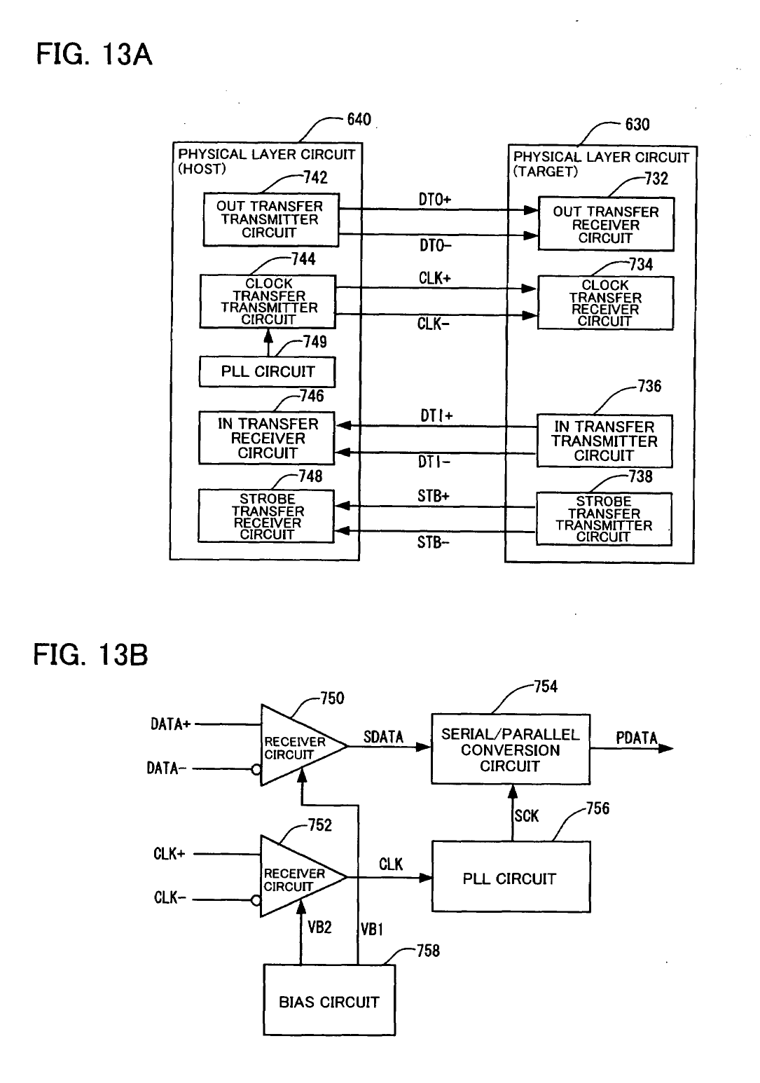

The configuration of the physical layer circuit is not limited to the configuration shown in FIG. 12B. Various modifications and variations may be made such as those shown in FIGS. 13A and 13B, for example. FIGS. 13A and 13B are circuit diagrams showing modifications of the configuration of the physical layer included in the high speed interface (I/F) circuit.

In a first modification shown in FIG. 13A, the host outputs differential data signals (OUT data) DTO+/− in synchronization with the edge of clock signals CLK+/−. Therefore, the target can sample and hold the data signals DTO+/− using the clock signals CLK+/−. The target generates and outputs differential strobe signals STB+/− based on the differential clock signals CLK+/− supplied from the host. The target outputs differential data signals (IN data) DTI+/− in synchronization with the edge of the strobe signals STB+/−. Therefore, the host can sample and hold the data signals DTI+/− using the strobe signals STB+/−.

In a second modification shown in FIG. 13B, a data receiver circuit 750 receives the differential data signals DATA+/−, and outputs serial data SDATA to a serial/parallel conversion circuit 754. A clock signal receiver circuit 752 receives the differential clock signals CLK+/−, and outputs the clock signal CLK to a phase locked loop (PLL) circuit 756 in the subsequent stage. The PLL circuit 756 generates a sampling clock signal SCK (multi-phase sampling clock signals at the same frequency but with different phases) based on the clock signal CLK, and outputs the sampling clock signal SCK to the serial/parallel conversion circuit 754. The serial/parallel conversion circuit 754 samples the serial data SDATA using the sampling clock signal SCK, and outputs parallel data PDATA.

In a portable telephone, for example, a host device (e.g., MPU, BBE/APP, or image processing controller) is mounted on a first circuit board in a first instrument section of the portable telephone in which buttons for inputting a telephone number or a character are provided. A display driver is mounted on a second circuit board in a second instrument section of the portable telephone in which a liquid crystal panel (LCD) or a camera device is provided.

According to related-art technology, data is transferred between the host device and the display driver by a CMOS voltage level parallel transfer. Therefore, the number of interconnects passing through a connection section (e.g., hinge) which connects the first and second instrument sections increases, whereby the degree of freedom relating to the design may be impaired, or EMI noise may occur.

According to the high-speed interface circuit shown in FIGS. 12 and 13, data is transferred between the host device and the display driver by a small-amplitude serial transfer. Therefore, the number of interconnects passing through the connection section which connects the first and second instrument sections can be reduced while reducing EMI noise.

Layout example of driver IC of liquid crystal display device shown in FIG. 11

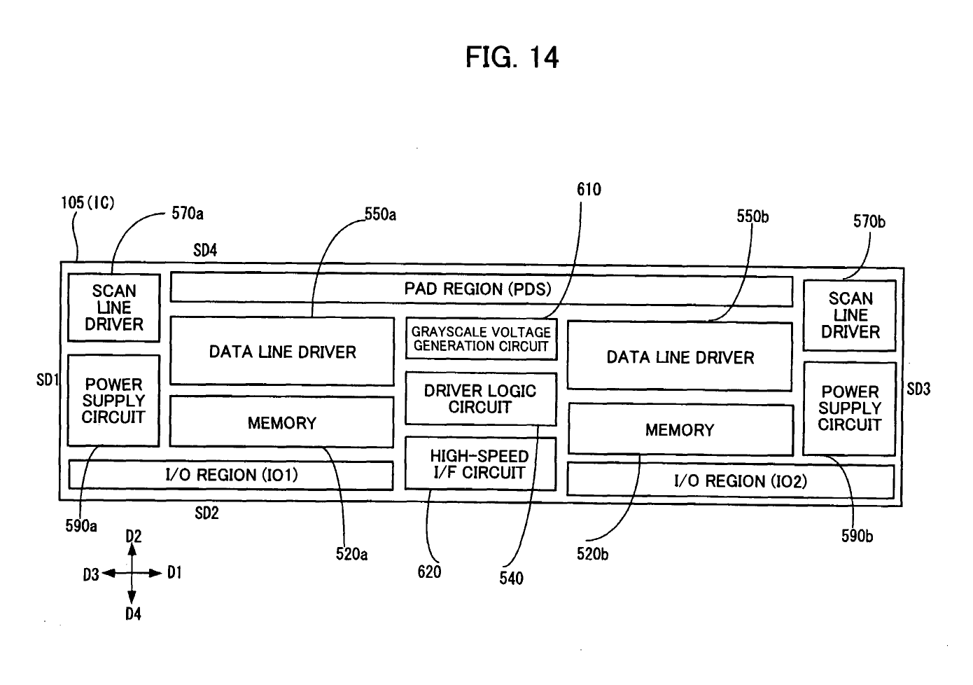

FIG. 14 is a view showing a layout example of the driver IC 105 of the liquid crystal display device.

As shown in FIG. 14, the high-speed I/F circuit 620, the driver logic circuit 540, and the grayscale voltage generation circuit 610 are disposed at the center. Data line drivers 550a and 550b, memories 520a and 520b, scan line drivers 570a and 570b, and power supply circuits 590a and 590b are symmetrically disposed in order.

In FIG. 14, I/O regions (IO1 and IO2) are pad regions which receive input signals. A pad region (PDS) is a region in which output pads are disposed in a row.

Type of Circuit used for IC

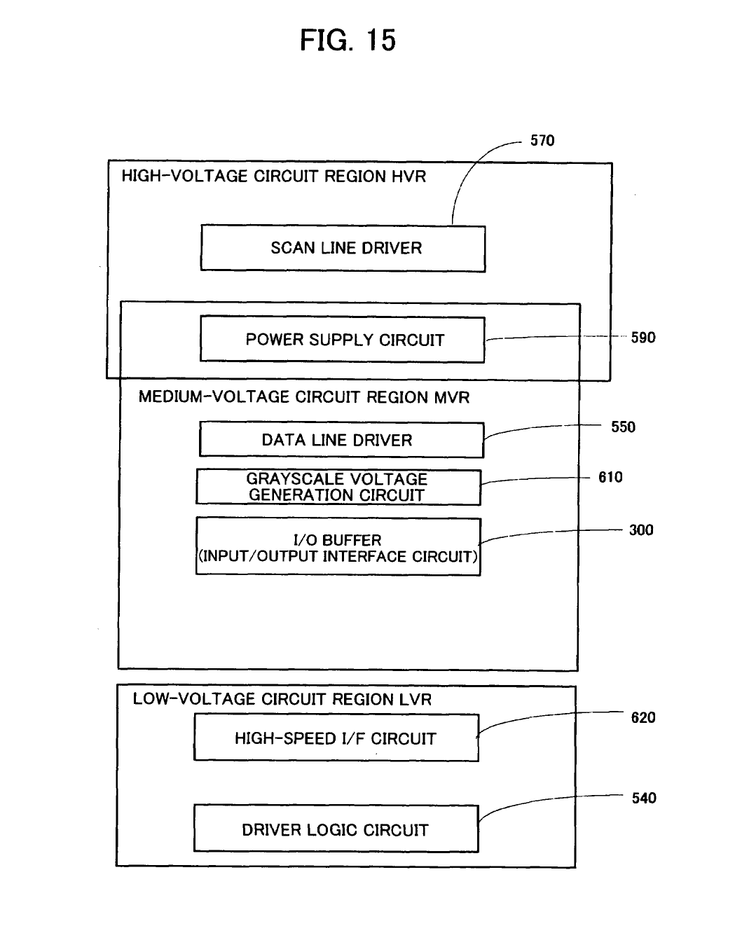

FIG. 15 is a view showing the type of circuit (classification depending on the breakdown voltage) used in the driver IC of the liquid crystal display device shown in FIG. 10.

As shown in FIG. 15, a low-voltage circuit region (LVR), a medium-voltage circuit region (MVR) of which the breakdown voltage is higher than that of the low-voltage circuit region LV, and a high-voltage circuit region (MVR) of which the breakdown voltage is higher than that of the medium-voltage circuit region MV are provided.

The high-speed I/F circuit block 620 and the driver logic circuit 540 are provided in the low-voltage circuit region (LVR). Part of the power supply circuit 590, the data line driver 550, the grayscale voltage generation circuit 610, and the I/O buffer (interface circuit) 300 are formed in the medium-voltage circuit region (MVR). The scan line driver 570 and part of the power supply circuit 590 are provided in the high-voltage circuit region (HVR).

Since three types of transistors which differ in breakdown voltage are provided in the IC according to this embodiment, the transistors of the I/O buffer (interface circuit) 300 can be easily changed from low-voltage transistors LVTr to medium-voltage transistors MVTr.

Device Structure (Triple-Well Structure) of First Circuit Block and Second Circuit Block

The integrated circuit device (IC) 105 according to the invention employs a triple-well structure, for example. The triple-well structure is employed on the assumption that the first circuit block and the second circuit block operate using different power supply systems.

Circuits which operate using different power supply systems can be reasonably formed in a compact manner using the triple-well structure. According to the triple-well structure, the transistors of the first circuit block and the transistors of the second circuit block can be electrically separated by a barrier (diode) formed between a second-conductivity-type substrate (e.g., PSUB) and a first first-conductivity-type well (e.g., NWL(1)). This makes it possible to adjacently provide the first circuit block and the second circuit block which are electrically separated.

The device structure is described below with reference to the drawings. FIGS. 16A and 16B are cross-sectional views showing the device configuration (triple-well structure) of the first circuit block and the second circuit block.

As shown in FIG. 16A, an N-type transistor NTR1 (first-conductivity-type transistor in a broad sense) included in a high-speed I/F circuit HB is formed in a P-type well (second-conductivity-type well in a broad sense) PWL(1).

A P-type transistor (second-conductivity-type transistor in a broad sense) PTR1 included in the high-speed I/F circuit HB is formed in an N-type well NWL(1) formed in a P-type substrate PSUB to enclose the P-type well PWL(1).

An N-type transistor NTR2 and a P-type transistor PTR2 included in a driver logic circuit LB (driver circuit) are not formed in the N-type well NWL(1) for the high-speed I/F circuit HB, but are formed in a region other than the N-type well NWL(1). Specifically, the P-type transistor PTR2 is formed in an N-type well NWL(2) separated from the N-type well NWL(1) for the high-speed I/F circuit HB, and the N-type transistor NTR2 is formed in the P-type substrate PSUB. This enables the transistors NTR1 and PTR1 which form the high-speed I/F circuit HB to be separated from the transistors NTR2 and PTR2 which form the driver logic circuit LB using the N-type well NWL(1) of the triple-well structure. Therefore, transmission of noise between the high-speed I/F circuit HB and the driver logic circuit LB can be prevented using the N-type well NWL(1) as a barrier. Accordingly, the high-speed I/F circuit HB (physical layer circuit PHY) is rarely adversely affected by noise produced by the driver logic circuit LB, whereby serial transfer transmission quality can be maintained. Moreover, the driver logic circuit LB and the like are rarely adversely affected by noise produced by the high-speed I/F circuit HB, whereby malfunction and the like can be prevented. Note that the transistors NTR2 and PTR2 of the driver logic circuit LB may be formed using a triple-well structure.

FIG. 16B shows a detailed configuration example of the triple-well structure. N-type wells NWLA1, NWLB1, NWLB2, and NWLB3 shown in FIG. 16B correspond to the N-type well NWL(1) shown in FIG. 16A. A P-type well PWLB1 shown in FIG. 16B corresponds to the P-type well PWL(1) shown in FIG. 16A. A N-type well NWLB4 shown in FIG. 16B corresponds to the N-type well NWL(2) shown in FIG. 16A.

In FIG. 16B, the N-type well NWLA1 is a deep well, and the N-type wells NWLB1, NWLB2, NWLB3, and NWLB4 are shallow wells. The N-type wells NWLB2 and NWLB3 are formed in the shape of rings. Therefore, the N-type well can be formed to enclose the P-type well PWLB1. A P+ region (second-conductivity-type diffusion region in a broad sense) electrically connected to a VSS power supply line is formed in the P-type wells PWLB2 and PWLB3. The potential of the P-type substrate PSUB can be stabilized by providing the P-type wells PWLB2 and PWLB3 and the P+ region 32, whereby noise tolerance can be increased.

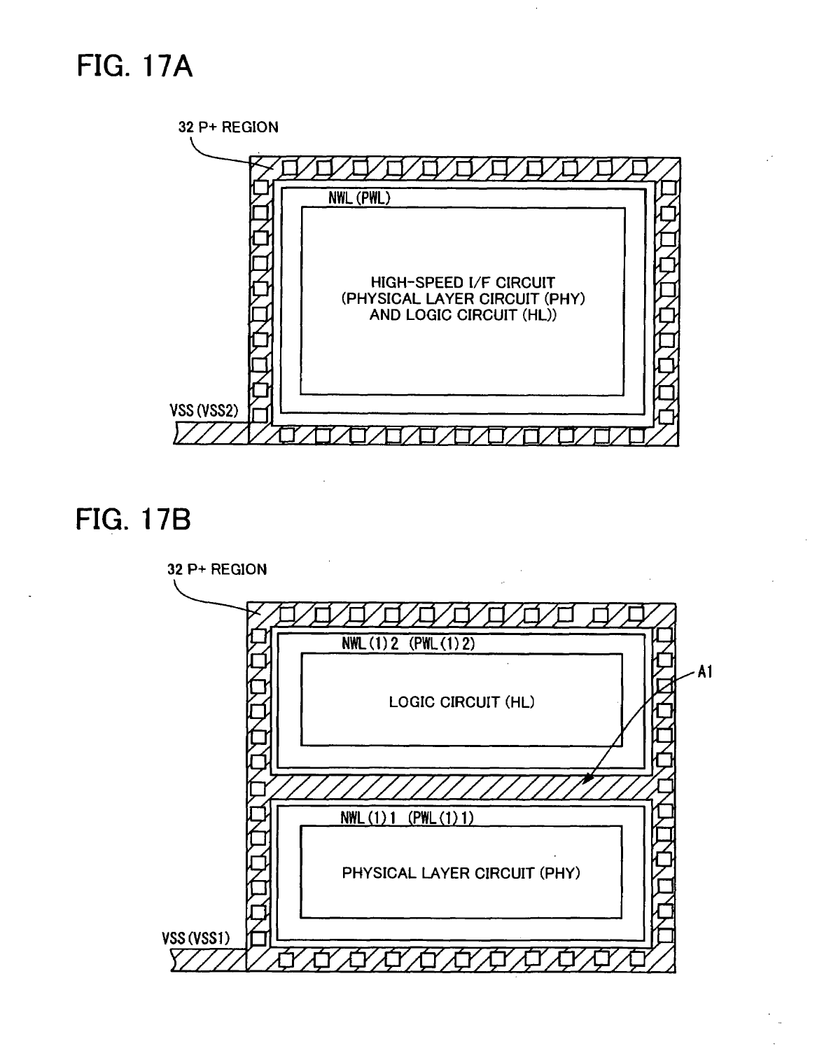

The substrate potential stabilization P+ region (second-conductivity-type diffusion region) 32 may be formed using a method described with reference to FIG. 17A or 17B, for example.

In FIG. 17A, the substrate potential stabilization P+ region 32 (see FIG. 16B) electrically connected to the power supply VSS (VSS2) of the driver logic circuit LB is disposed in the shape of a ring. The P+ region 32 is connected to the P-type substrate PSUB (see FIG. 16B). Specifically, a guard ring formed of the P+ region 32 electrically connected to the VSS (VSS2) power supply line through a contact is provided to enclose the N-type well NWL(1) in which the high-speed I/F circuit HB is formed. Therefore, the potential of the P-type substrate PSUB on the periphery of the N-type well NWL(1) is stabilized, whereby a situation in which noise produced by the high-speed I/F circuit HB is transmitted to the driver logic circuit LB and the like can be effectively prevented.

In FIG. 17B, the physical layer circuit PHY included in the high-speed I/F circuit HB is formed in an N-type well NWL(1)1 of the triple-well structure, and the logic circuit HL is formed in an N-type well NWL(1)2 of the triple-well structure formed separately form the N-type well NWL(1)1. Specifically, an N-type transistor which forms the physical layer circuit PHY is formed in the P-type well PWL(1)1. A P-type transistor which forms the physical layer circuit PHY is formed in an N-type well NWL(1)1 formed in the P-type substrate PSUB to enclose the P-type well PWL(1)1.

An N-type transistor which forms the logic circuit HL is formed in a P-type well PWL(1)2. A P-type transistor which forms the logic circuit HL is formed in an N-type well NWL(1)2 formed in the P-type substrate PSUB to enclose the P-type well PWL(1)2.

In FIG. 17B, the physical layer circuit PHY and the logic circuit HL are formed in different wells of the triple-well structure. Therefore, the physical layer circuit PHY is rarely adversely affected by noise produced by the logic circuit HL, whereby serial transfer transmission quality can be maintained. Moreover, the logic circuit HLis rarely adversely affected by noise produced by the physical layer circuit PHY, whereby malfunction and the like can be prevented. The N-type well NWL(1)2 in which the logic circuit HL is formed serves as a barrier to reduce transmission of noise between the physical layer circuit PHY and the driver logic circuit block LB.

In FIG. 17B, the VSS (VSS2) power supply line is provided in the high-speed I/F circuit HB. Specifically, the VSS (VSS2) power supply line is also provided in the high-speed I/F circuit HB in addition to the periphery of the high-speed I/F circuit HB, as indicated by A1 in FIG. 17B. The P+ region 32 connected to the VSS power supply line thus provided is formed in the P-type substrate PSUB between the N-type well NWL(1)1 and the N-type well NWL(1)2.

Therefore, the potential of the P-type substrate PSUB positioned between the N-type well NWL(1)1 and the N-type well NWL(1)2 is stabilized by the P+ region 32 formed between the N-type well NWL(1)1 and the N-type well NWL(1)2. As a result, noise produced by the logic circuit HL is rarely transmitted to the physical layer circuit PHY, and noise produced by the physical layer circuit PHY is rarely transmitted to the logic circuit HL. Moreover, the protection circuit between the power supplies VSS2 and VSS for the high-speed I/F circuit HB can be efficiently arranged by providing the VSS (VSS2) power supply line in this manner, whereby layout efficiency can be improved while improving reliability.

The method of forming the N-type well and the P+ region in the high-speed I/F circuit HB is not limited to the methods shown in FIGS. 17A and 17B. For example, the N-type well in which the analog circuit of the physical layer circuit PHY is formed may be separated from the N-type well in which the high-speed logic circuit of the physical layer circuit PHY is formed. This further improves noise tolerance.

Although the embodiments of the invention have been described in detail above, those skilled in the art would readily appreciate that many modifications are possible in the embodiments without materially departing from the novel teachings and advantages of the invention. Accordingly, such modifications are intended to be included within the scope of the invention.

Any term cited with a different term having a broader meaning or the same meaning at least once in the specification and the drawings can be replaced by the different term in any place in the specification and the drawings. The configurations and the operations of the circuit and the electronic instrument are not limited to those described with reference to the above embodiments. Various modifications and variations may be made.

According to the present invention, electrostatic discharge protection (electrostatic discharge resistance) of an integrated circuit device including an interface circuit provided between circuits (low-voltage circuits) which differ in power supply system can be improved by a simple configuration by changing transistors which form the interface circuit from low-voltage transistors (LVTr) to medium-voltage transistors (MVTr) having a higher breakdown voltage as compared with the low-voltage transistors (LVTr). Therefore, the reliability of the IC can be effectively improved.

The invention is particularly suitably used for an IC utilizing low-voltage elements and medium-voltage elements in combination, such as a driver IC of a liquid crystal display device.

Although only some embodiments of the invention have been described in detail above, those skilled in the art would readily appreciate that many modifications are possible in the embodiments without materially departing from the novel teachings and advantages of the invention. Accordingly, such modifications are intended to be included within the scope of the invention.

What is claimed is:

1. An integrated circuit device comprising:
a first circuit block;
a second circuit block that operates using a power supply system differing from that of the first circuit block; and
an interface circuit provided between the first circuit block and the second circuit block,
gate insulating films of some or all of a plurality of insulated gate transistors that form the interface circuit having a thickness larger than a thickness of a gate insulating film of at least one insulated gate transistor included in at least one of the first circuit block and the second circuit block.

2. The integrated circuit device as defined in claim 1,
the interface circuit including at least one of a first buffer circuit and a second buffer circuit;
the first buffer circuit including a first output buffer that buffers a signal from the first circuit block and outputs the buffered signal to a first signal path, and a first input buffer that buffers a signal transmitted from the first output buffer through the first signal path and supplies the buffered signal to the second circuit block;
the second buffer circuit including a second output buffer that buffers a signal from the second circuit block and outputs the buffered signal to a second signal path, and a second input buffer that buffers a signal transmitted from the second output buffer through the second signal path and supplies the buffered signal to the first circuit block;
the first output buffer and the second input buffer operating at a power supply voltage of the first circuit block;
the first input buffer and the second output buffer operating at a power supply voltage of the second circuit block; and
gate insulating films of insulated gate transistors that form the first input buffer and the second input buffer having a thickness larger than a thickness of a gate insulating film of at least one insulated gate transistor that forms at least one of the first circuit block and the second circuit block.

3. The integrated circuit device as defined in claim 2,
gate insulating films of insulated gate transistors that form the first output buffer and the second output buffer having a thickness larger than a thickness of a gate insulating film of at least one insulated gate transistor that forms at least one of the first circuit block and the second circuit block.

4. The integrated circuit device as defined in claim 1,
the first circuit block operating using a first high-potential power supply and a first low-potential power supply; the second circuit block operating using a second high-potential power supply and a second low-potential power supply; and an electrostatic discharge protection circuit for noise blocking and electrostatic discharge protection being provided between a power supply node connected to the first low-potential power supply and a power supply node connected to the second low-potential power supply.

5. The integrated circuit device as defined in claim 4,
the electrostatic discharge protection circuit including bidirectional diodes, the bidirectional diodes being formed by connecting at least one first diode and at least one second diode in parallel, a forward direction of the at least one first diode being a direction from the first low-potential power supply to the second low-potential power supply, and a forward direction of the at least one second diode being a direction from the second low-potential power supply to the first low-potential power supply.

6. The integrated circuit device as defined in claim 4,
the integrated circuit device further including: a first inter-power-supply protection element provided between a power supply node connected to the first high-potential power supply and a power supply node connected to the first low-potential power supply; and a second inter-power-supply protection element provided between a power supply node connected to the second high-potential power supply and a power supply node connected to the second low-potential power supply.

7. The integrated circuit device as defined in claim 1,
the first circuit block being a high-speed interface circuit that transfers data through a serial bus; and
the high-speed interface circuit including a physical layer circuit that includes an analog circuit, and a logic circuit.

8. The integrated circuit device as defined in claim 1,
the second circuit block being a driver logic circuit that generates a display control signal for driving a display device.

9. The integrated circuit device as defined in claim 1,
channel regions of the gate insulating films of the interface circuit that have a thickness larger than the thickness of the gate insulating films of the insulated gate transistors of the first circuit block and the second circuit block being subjected to a doping process that reduces a threshold value.

10. The integrated circuit device as defined in claim 1,
the integrated circuit device including a low-voltage circuit region, a medium-voltage circuit region having a breakdown voltage higher than that of the low-voltage circuit region, and a high-voltage circuit region having a breakdown voltage higher than that of the medium-voltage circuit region;
at least part of the first circuit block being formed in the low-voltage circuit region;
at least part of the second circuit block being formed in the low-voltage circuit region; and
the first input buffer and the second input buffer of the interface circuit being formed in the medium-voltage circuit region.

11. The integrated circuit device as defined in claim 10,
the integrated circuit device further including a data line driver block that drives a data line of the display device, the data line driver block being formed in the medium-voltage circuit region.

12. The integrated circuit device as defined in claim 10,
the integrated circuit device further including a scan line driver block that drives a scan line of a display device, the scan line driver block being formed in the high-voltage circuit region.

13. The integrated circuit device as defined in claim 10,
the integrated circuit device including:
a power supply circuit block formed in the high-voltage circuit region and the medium-voltage circuit region; and
a grayscale voltage generation circuit formed in the medium-voltage circuit region.

14. The integrated circuit device as defined in claim 1,
a first-conductivity-type transistor that forms the first circuit block being formed in a second-conductivity-type well;
a second-conductivity-type transistor that forms the first circuit block being formed in a first first-conductivity-type well, the first first-conductivity-type well being formed in a second-conductivity-type substrate to enclose the second-conductivity-type well;
a first-conductivity-type transistor that forms the second circuit block being formed in the second-conductivity-type substrate; and
a second-conductivity-type transistor that forms the second circuit block being formed in a second first-conductivity-type well that differs from the first first-conductivity-type well for the first circuit block.

15. An electronic instrument comprising:
the integrated circuit device as defined in claim 1; and
a display device driven by the integrated circuit device.
